(19) United States
(12) Patent Application Publication
(10) Pub. No.: US 2007/0052084 A1
(43) Pub. Date: Mar. 8, 2007

(54) High density interconnect assembly comprising stacked electronic module

(76) Inventor: John V. Kennedy, Irvine, CA (US)

Correspondence Address: W. ERIC BOYD, ESQ.;IRVINE SENSORS CORPORATION, 3001 REDHILL AVENUE, BUILDING 3, SUITE 108, COSTA MESA, CA, 92626, US

(21) Appl. No.: 11/499,403

(22) Filed: Aug. 4, 2006

Related U.S. Application Data
(60) Provisional application No. 60/711,375, filed on Aug. 26, 2005.

(51) Int. Cl. H01L 23/02; H01L 21/00

(52) U.S. Cl. 257/686; 438/109; 257/E23.173

(57) ABSTRACT

A microelectronic module is provided with one or more first conductive pads on at least one of the exterior surfaces of the module for electrical interconnection of the functionality of the module to one or more second conductive pads on a second surface such as printed circuit board. A high density interposer assembly is disposed between the first conductive pads and second conductive pads. Outwardly projecting conductive elements on the interposer assembly are in registration with the first and second conductive pads whereby, when the interposer assembly is interposed between the first and second conductive pads, a mechanical connection is made between the elements, resulting in an electrical path between the first and second conductive pads.

### CROSS REFERENCE TO RELATED APPLICATIONS

This application is related to U.S. provisional patent application No. 60/711,375 entitled “High Density Interconnect Scheme For Stacked Electronic Modules”, filed Aug. 26, 2005, which is incorporated herein by reference and to which priority is claimed pursuant to 35 U.S.C. 119.

### STATEMENT REGARDING FEDERALLY SPONSORED RESEARCH AND DEVELOPMENT

The invention was made under a contract with an agency of the United States Government. The contract number is classified as of the date of filing of the instant application.

### BACKGROUND OF THE INVENTION

1. Background of the Invention

The invention relates generally to stacked microelectronic modules. Specifically, the invention relates to a device comprised of stacked microelectronic layers which are interconnected to external circuitry by means of a high density interconnect assembly.

In the electronics industry, there are significant advantages to stacking and interconnecting integrated circuit packages, modified integrated circuit packages and/or bare die integrated circuit chips, e.g., application specific integrated circuits, to create high density, three-dimensional, microelectronic modules.

Typical in module fabrication, I/O pads of the individual integrated circuit layers are interconnected using a variety of technologies, including conductive vias, metallized, rerouted traces and/or metallized T-connect structures fabricated on the periphery of the module.

Examples of T-connected microelectronic module structures are disclosed in U.S. Pat. No. 6,967,411 to Eide, U.S. Pat. No. 6,806,559 to Gann, et al., U.S. Pat. No. 6,784,547 to Pepe, et al., U.S. Pat. No. 6,734,370 to Yamaguchi, et al., U.S. Pat. No. 6,706,971 to Albert, et al., U.S. Pat. No. 6,117,704 to Yamaguchi, et al., U.S. Pat. No. 6,072,234 to Camien, et al., U.S. Pat. No. 5,953,588, to Camien, et al., U.S. Pat. No. 4,953,533 to Go, U.S. Pat. No. 5,104,820 to Go, and U.S. Pat. No. 5,688,721 to Johnson, all assigned to common assignee, Irvine Sensors Corp. and each of which is incorporated fully herein by reference.

A fundamental advantage of stacking integrated circuit layers is the maximum utilization of limited surface area on a printed circuit board. Stacking integrated circuit packages provides increased circuit density without requiring additional printed circuit board space. Further, stacking integrated circuit packages reduces signal lead lengths between the stacked components, reduces parasitic inductance and capacitance, which in turn, allows the circuits to operate at very high clock speeds.

Prior art methods of connecting microelectronic modules to external conductive circuitry (i.e., conductive traces or pads on a separate printed circuit board) include the use of conductive epoxies, reflowed solder balls or solder pastes or wire bonding. In a typical layered module, conductive metal traces route appropriate I/O pads of the integrated circuits in the layers of the module to the edge of the layer to form an access lead on a peripheral surface of the module assembly. Metallized T-connect structures are then defined upon the access lead for the further rerouting of the traces to predefined conductive pads or locations upon the peripheral surface of the module. Finally, the conductive pads on the exterior peripheral surfaces of the microelectronic module are then electrically connected to conductive traces or pads on external circuitry using the above solder or wire bond methods.

The above prior art methods of module-to-printed circuit board connection have certain undesirable attributes such as exposing the module to solder reflow temperatures which can damage circuitry within the stack, the layer interconnects or layer bonding. Further undesirable attributes of the above methods include the difficulty in removing the module from the external circuitry once it is connected and the inability to test the stack on the external circuitry to ensure module functionality prior to permanently connecting the module to the printed circuit board.

What is needed is a method and device that allows for the selective attachment and removal of a microelectronic module from external circuitry such as a printed circuit board without the need for reflowing the solider connections, breaking wire bonds or damaging the module or external circuit.

2. Brief Summary of the Invention

A microelectronic module comprising one or more layers, in which at least one layer comprises one or more integrated circuit chips, is provided with one or more first conductive pads on at least one of the exterior surfaces of the module for electrical interconnection of the functionality of the module to one or more second conductive pads on an second surface such as printed circuit board. The first conductive pads are in registration with the second conductive pads.

A high density interconnection assembly is disposed between the first conductive pads and second conductive pads and is comprised of one or more generally elongate, compressible conductive elements retained within and outwardly projecting from a dielectric layer. The outwardly projecting conductive elements are in registration with the first and second conductive pads whereby, when the interconnection assembly is interposed between the first and second conductive pads, a mechanical connection is made between the elements, resulting in an electrical path between the first and second conductive pads.

While the claimed apparatus and method has or will be described for the sake of grammatical fluidity with functional explanations, it is to be expressly understood that the claims, unless expressly formulated under 35 USC 112, are not to be construed as necessarily limited in any way by the construction of “means” or “steps” limitations, but are to be accorded the full scope of the meaning and equivalents of the definition provided by the claims under the judicial doctrine of equivalents, and in the case where the claims are expressly formulated under 35 USC 112, are to be accorded full statutory equivalents under 35 USC 112.

### BRIEF DESCRIPTION OF THE DRAWINGS

FIG. 1 is a compressible conductor of the invention comprising one or more strands of wire in a generally elongate, cylindrical form.

FIG. 2 is a cross-section of a perspective view of the high-density interposer assembly of the invention.

FIGS. 3 and 3A illustrate a representative electronic module of the invention and shows access leads accessible on a peripheral surface thereof and a cross-section thereof.

FIG. 4 shows an exploded view the electronic module of the invention for connection to an external circuit by means of an interposer assembly and compression frame.

The invention and its various embodiments can now be better understood by turning to the following detailed description of the preferred embodiments which are presented as illustrated examples of the invention defined in the claims. It is expressly understood that the invention as defined by the claims may be broader than the illustrated embodiments described below.

### DETAILED DESCRIPTION OF THE PREFERRED EMBODIMENT

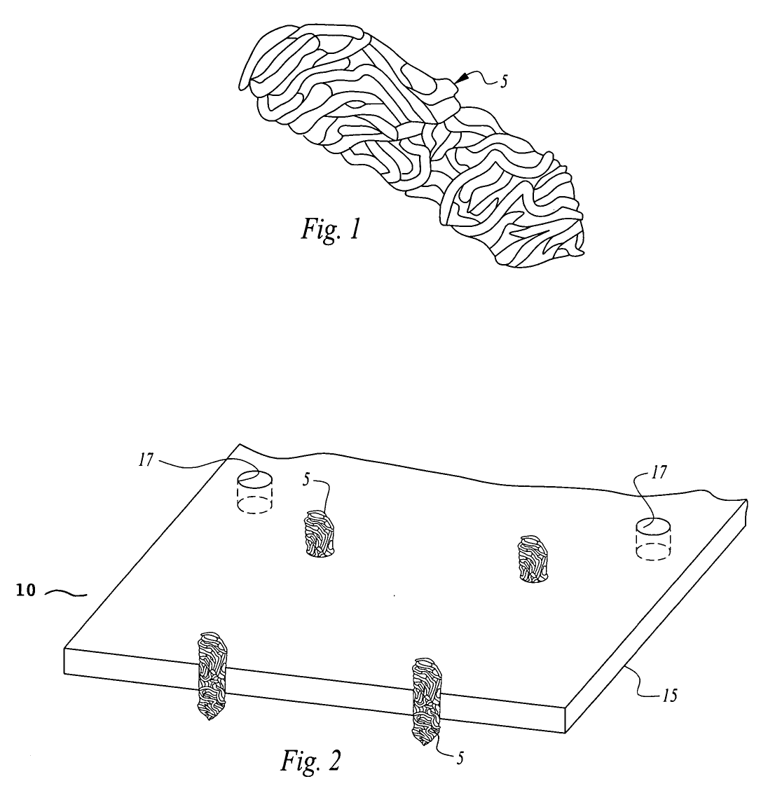

Turning now to the figures wherein like numerals identify like elements among the several views, FIG. 1 illustrates the compressible conductor 5 of the invention.

Compressible conductor 5 is preferably manufactured from a single strand of 0.002″ gold plated beryllium copper wire compressed into a cylindrical shape as are available from Tecknit, Inc.

Compressible conductor 5 is not limited to a single strand construction and may be desirably fabricated from a plurality of wire strands or other electrically conductive materials with suitable mechanical and electrical properties for the end application of the conductor as is well-known in the materials arts. The preferred embodiment of compressible conductor 5, as illustrated, is a 0.020″ diameter cylindrical element. The single wire strand construction has the desirable attributes of relatively high temperature operation, reduced signal path and associated lower inductance and distortion. A random wire orientation in the structure of compressible conductor 5 assists in the cancellation of electronic fields created by electrical conduction and has the further desirable attribute of compressibility of between 15% to 30% of its nominal original height.

This form of conductor can be repeatedly (i.e., twenty or more times) compressed and decompressed while still retaining its nominal original height. Compressible conductor 5 may selectively be used with or without solid contact pins on the terminal ends thereof.

As illustrated in FIG. 2, in a preferred embodiment of the invention, an interposer assembly 10 is provided comprising a dielectric layer 15 and one or more compressible conductors 5. Dielectric layer 15 is preferably formed from a non-conductive plastic material such as ULTEM 1000 as is available from Gehr Plastics, Inc.

One or more compressible conductors 5 are disposed within and through the thickness of a dielectric layer 15 wherein the terminal ends of compressible conductor 5 outwardly depend from the opposing first and second major planar surfaces of dielectric layer 15.

A preferred method of fabricating interposer assembly 10 is to drill through-holes in the requisite pattern through dielectric layer 15 for the retention of the body of compressible conductor 5. In this manner, the respective terminal ends of compressible conductor 5 are accessible from the respective sides of dielectric layer 15 and provide an electrically conductive path through the thickness thereof. One or more registration holes 17 are preferably provided through dielectric layer 15 for the subsequent registration of interposer assembly 10 with the conductive pads between which it will be disposed. Registration holes 17 are used to maintain alignment of conductors 5 with the respective conductive pads upon which they will be disposed by using a registration pin mount when interposer assembly 10 is mounted in the invention as is more fully discussed below.

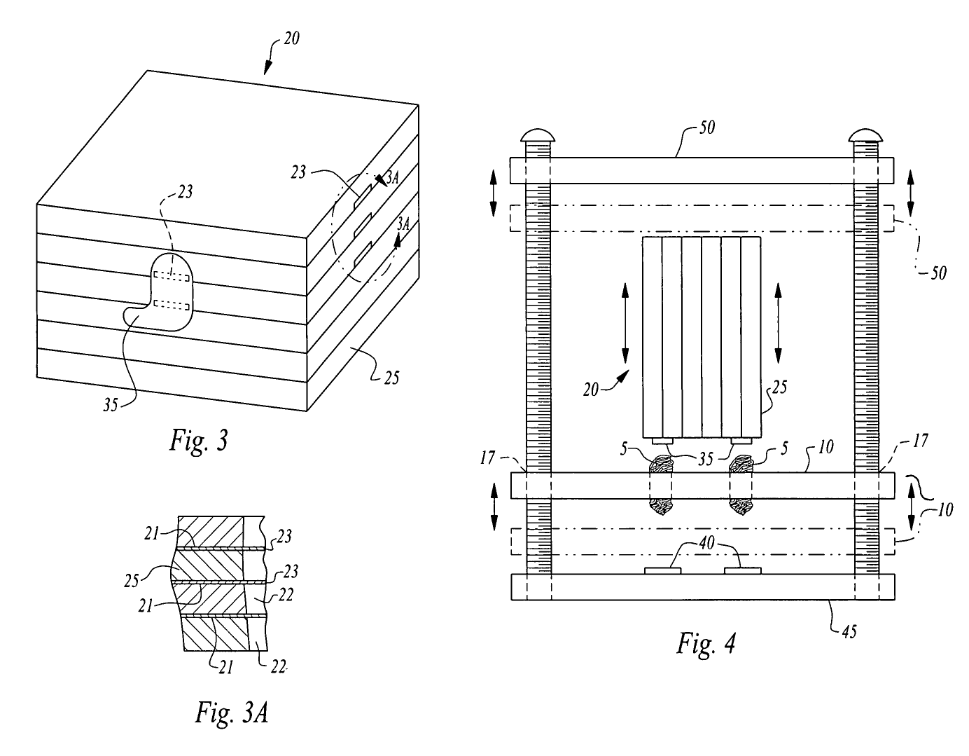

Turning to FIG. 3A, a magnified cross-section of a portion of a preferred embodiment of a three-dimensional microelectronic module 20 is shown wherein one or more layers containing bare die integrated circuit chips are stacked and bonded together. The individual layers comprise necessary metallized traces 21 and passivation layer 22 for the rerouting of electronic signals from the integrated circuit chips in the layers to the edges of the layers to form access leads 23 terminating at the periphery of module 20.

By way of example and not by limitation, module 20 may comprise layers of bare integrated circuit die (i.e., ASICs), commercial off the shelf (COTS) packaged parts, modified prepackaged parts or neo-layers as is disclosed in the above patents incorporated herein by reference.

Module 20 is comprised of individual layers 25 that are bonded together with a suitable adhesive to form an integral assembly. One or more of layers 25 comprise integrated circuitry but may further comprise discrete embedded components such as resistors, inductors, capacitors and the like.

User-defined metallized conductive traces 21 are formed upon a planar surface of each layer 25 as needed so as to reroute electronic signals, such as clock, enable, data, power, ground, etc. to the edge of the layer to form access lead 23. Access leads 23 are selectively provided on one or a plurality of module peripheral surfaces.

As better seen in FIGS. 3 and 4, metallized traces may be used to interconnect access leads 23 between the layers in the module as well as rerouted to create one or more first contact pads 35 to electrically connect the module to one or more second contact pads 40 on an external surface such as an external printed circuit board 45.

FIG. 4 shows a preferred configuration of the module and assembly of the invention. Complementary first and second conductive pads 35 and 40 are fabricated on module 20 and printed circuit board 45 respectively and are in substantial registration with each other. Interposer assembly 10 is fabricated whereby the requisite compressible conductors 5 are registered and oriented to be in mechanical contact with the respective first and second conductive pads when interposer assembly 10 is disposed and aligned between module 20 and printed circuit board 45.

In a preferred embodiment of the invention, compression frame 50 is provided for the urging of module 20 normal to printed circuit board 45 to control compression and to retain the module on the printed circuit board using, for instance, threaded means, such as screws, nut and bolt and the like.

As can be readily seen, when module 20 is compressed upon printed circuit board 45, such as by means of compression frame 50, and when compressible conductors 5 and first and second contact pads 35 and 40 are in proper registration, compressible conductors 5 are put in mechanical connection with first and second contact pads 35 and 40, creating an electrical connection between them.

Alternately, when the compression source is removed, module 20 may be mechanically separated from interposer assembly 10, providing the benefit of the selective insertion or removal a module from an external circuit without the need for reflowing solder ball connections, breaking wire bonds or conductive epoxy connections. Such a configuration is ideal for testing module performance and functionality in an external circuit without creating permanent metallurgical or adhesive circuit connections.

In an alternative preferred embodiment, not shown, module 20 may be fixedly disposed within a cavity or housing and the interposer assembly and printed circuit board compressed upon the module.

It is noted that any suitable mechanical means may be used to fixedly retain the module, interposer assembly and external circuitry or to apply the appropriate compressive force between first and second conductive pads to create a mechanical and electrical connection between the respective pads.

Therefore, it must be understood that the illustrated embodiment has been set forth only for the purpose of example and that it should not be taken as limiting the invention as defined by the following claims. For example, notwithstanding the fact that the elements of a claim are set forth below in a certain combination, it must be expressly understood that the invention includes other combinations of fewer, more or different elements, which are disclosed even when not initially claimed in such combinations.

The words used in this specification to describe the invention and its various embodiments are to be understood not only in the sense of their commonly defined meanings, but to include by special definition in this specification, structure, material or acts beyond the scope of the commonly defined meanings. Thus, if an element can be understood in the context of this specification as including more than one meaning, then its use in a claim must be understood as being generic to all possible meanings supported by the specification and by the word itself.

The definitions of the words or elements of the following claims are therefore defined in this specification to include not only the combination of elements which are literally set forth, but all equivalent structure, material or acts for performing substantially the same function in substantially the same way to obtain substantially the same result. In this sense it is therefore contemplated that an equivalent substitution of two or more elements may be made for any one of the elements in the claims below or that a single element may be substituted for two or more elements in a claim.

Although elements may be described above as acting in certain combinations and even initially claimed as such, it is to be expressly understood that one or more elements from a claimed combination can, in some cases be excised from the combination and that the claimed combination may be directed to a sub-combination or variation of a sub combination.

Insubstantial changes from the claimed subject matter as viewed by a person with ordinary skill in the art, now known or later devised, are expressly contemplated as being equivalent within the scope of the claims. Therefore, obvious substitutions now or later known to one with ordinary skill in the art are defined to be within the scope of the defined elements.

The claims are thus to be understood to include what is specifically illustrated and described above, what is conceptually equivalent, what can be obviously substituted and also what essentially incorporates the fundamental idea of the invention.

I claim:

1. A high density interconnect assembly comprised of:
A electronic module comprising a stack of layers, at least one of said layers comprising an integrated circuit chip,
said electronic module further comprising a peripheral surface having a first conductive pad disposed thereon,
said first conductive pad in electrical communication with said integrated circuit chip,
a second conductive pad disposed on an external circuit,
an interposer assembly comprising a dielectric layer having opposing first and second major planar surfaces and a thickness and further comprising a compressible conductor extending through said thickness and outwardly depending from said opposing first and second major planar surfaces,
said interposer assembly disposed and compressed between said first conductive pad and said second conductive pad whereby said compressive conductor is in mechanical contact with said first conductive pad and said second conductive pad.

2. The high density interconnect assembly of claim 1 further comprising a compression frame.

3. The high density interconnect assembly of claim 1 wherein at least one of said layers is comprised of an ASIC.

4. The high density interconnect assembly of claim 1 wherein at least one of said layers is comprised of a prepackaged integrated circuit chip.

5. The high density interconnect assembly of claim 1 wherein at least one of said layers is comprised of a modified prepackage integrated circuit chip.

6. The high density interconnect assembly of claim 1 wherein at least one of said layers is comprised of a neo-layer.

7. The high density interconnect assembly of claim 1 wherein the module is fixedly retained within a cavity.
